(19) United States
(12) Patent Application Publication
(10) Pub. No.: US 2005/0178667 A1
(43) Pub. Date: Aug. 18, 2005

(54) Method and systems for controlling current in electrochemical processing of microelectronic workpieces

(76) Inventors: Gregory J. Wilson, Kalispell, MT (US); Kenneth Gibbons, Kalispell, MT (US); Paul R. McHugh, Kalispell, MT (US)

Correspondence Address: WALLENSTEIN WAGNER & ROCKEY, LTD., 311 SOUTH WACKER DRIVE, 53RD FLOOR, CHICAGO, IL, 60606, US

(21) Appl. No.: 11/033,783

(22) Filed: Jan. 12, 2005

Related U.S. Application Data
(63) Continuation of application No. 10/158,220, filed on May 29, 2002.
(60) Provisional application No. 60/294,690, filed on May 30, 2001.

(51) Int. Cl. C25D 11/02; C25D 5/22; H01L 21/288

(52) U.S. Cl. 205/123; 205/157; 205/171

(57) ABSTRACT

A method and system for electrolytically processing a microelectronic workpiece. In one embodiment, the method includes contacting the workpiece with an electrolytic fluid, positioning one or more electrodes in electrical communication with the workpiece, directing an electrical current through the electrolytic fluid from the electrodes to the workpiece or vice versa, and actively changing a distribution of the current at the workpiece during the process. For example, the current can be changed such that a current ratio of at least one electrical current to the sum of the electrical currents shifts from a first current ratio value to a second current ratio value. Accordingly, the current applied to the workpiece can be adjusted to achieve a target shape for a conductive layer on the workpiece, or to account for temporally and/or spatially varying characteristics of the electrolytic process.

### CROSS-REFERENCE TO RELATED APPLICATIONS

The present application claims priority to Provisional Application No. 60/294,690, filed May 30, 2001, which is incorporated herein in its entirety by reference.

### TECHNICAL FIELD

This application relates to methods and systems for enhancing the performance of plating and other electrochemical processes.

### BACKGROUND

Microelectronic devices, such as semiconductor devices and field emission displays, are generally fabricated on and/or in microelectronic workpieces using several different types of machines (“tools”). Many such processing machines have a single processing station that performs one or more procedures on the workpieces. Other processing machines have a plurality of processing stations that perform a series of different procedures on individual workpieces or batches of workpieces. In a typical fabrication process, one or more layers of conductive materials are formed on the workpieces during deposition stages. The workpieces are then typically subject to etching and/or polishing procedures (i.e., planarization) to remove a portion of the deposited conductive layers for forming electrically isolated contacts and/or conductive lines.

Plating tools that plate metals or other materials on the workpieces are becoming an increasingly useful type of processing machine. Electroplating and electroless plating techniques can be used to deposit copper, solder, permalloy, gold, silver, platinum and other metals onto workpieces for forming blanket layers or patterned layers. A typical copper plating process involves depositing a copper seed layer onto the surface of the workpiece using chemical vapor deposition (CVD), physical vapor deposition (PVD), electroless plating processes, or other suitable methods. After forming the seed layer, a blanket layer or patterned layer of copper is plated onto the workpiece by applying an appropriate electrical potential between the seed layer and an anode in the presence of an electroprocessing solution. The workpiece is then cleaned, etched and/or annealed in subsequent procedures before transferring the workpiece to another processing machine.

FIG. 1 illustrates an embodiment of a single-wafer processing station 1 that includes a container 2 for receiving a flow of electroplating solution from a fluid inlet 3 at a lower portion of the container 2. The processing station 1 can include an anode 4, a plate-type diffuser 6 having a plurality of apertures 7, and a workpiece holder 9 for carrying a workpiece 5. The workpiece holder 9 can include a plurality of electrical contacts for providing electrical current to a seed layer on the surface of the workpiece 5. The seed layer acts as a cathode when it is biased with a negative potential relative to the anode 4. In operation the electroplating fluid flows around the anode 4, through the apertures 7 in the diffuser 6 and against the plating surface of the workpiece 5. The electroplating solution is an electrolyte that conducts electrical current between the anode 4 and the cathodic seed layer on the surface of the workpiece 5. Therefore, ions in the electroplating solution are reduced at the surface of the workpiece 5 to form a metal film.

The plating machines used in fabricating microelectronic devices must meet many specific performance criteria. For example, many processes must be able to form small contacts in vias that are less than 0.5 μm wide, and are desirably less than 0.1 μm wide. The plated metal layers accordingly often need to fill vias or trenches that are on the order of 0.1 μm wide, and the layer of plated material should also be deposited to a desired, uniform thickness across the surface of the workpiece 5. One factor that influences the uniformity of the plated layer is the current density at the workpiece. Current density is influenced by the mass transfer of electroplating solution at the surface of the workpiece. This parameter is generally influenced by the velocity of the flow of the electroplating solution perpendicular to the surface of the workpiece. Other factors that influence the current density at the workpiece are the design of the electroplating chamber, the position of the anodes, the initial seed layer resistance and the current applied to the anodes.

One concern of existing electroplating equipment is providing a uniform mass transfer at the surface of the workpiece. Referring to FIG. 1, existing plating tools generally use the diffuser 6 to enhance the uniformity of the fluid flow perpendicular to the face of the workpiece. Although the diffuser 6 improves the uniformity of the fluid flow, it produces a plurality of localized areas of increased flow velocity perpendicular to the surface of the workpiece 5 (indicated by arrows 8). The localized areas generally correspond to the position of the apertures 7 in the diffuser 6. The increased velocity of the fluid flow normal to the substrate in the localized areas increases the mass transfer of the electroplating solution in these areas. This typically results in faster plating rates in the localized areas over the apertures 7. Although many different configurations of apertures have been used in plate-type diffusers, these diffusers may not provide adequate uniformity for the precision required in many current applications.

Another concern of existing plating tools is that the diffusion layer in the electroplating solution adjacent to the surface of the workpiece 5 can be disrupted by gas bubbles or particles. For example, bubbles can be introduced to the plating solution by the plumbing and pumping system of the processing equipment, or they can evolve from inert anodes. Consumable anodes are often used to prevent or reduce the evolvement of gas bubbles in the electroplating solution, but these anodes erode and they can form a passivated film surface that must be maintained. Consumable anodes, moreover, often generate particles that can be carried in the plating solution. As a result, gas bubbles and/or particles can flow to the surface of the workpiece 5, which disrupts the uniformity and affects the quality of the plated layer.

Still another challenge of plating uniform layers is providing a desired electrical field at the surface of the workpiece 5. The distribution of electrical current in the plating solution is a function of the uniformity of the seed layer across the contact surface, the resistance of the seed layer, the configuration/condition of the anode, and the configuration of the chamber. However, the current density profile on the plating surface can change. For example, the current density profile typically changes during a plating cycle because plating material covers the seed layer, or it can change over a longer period of time because the shape of consumable anodes changes as they erode and the concentration of constituents in the plating solution can change. Therefore, it can be difficult to maintain a desired current density at the surface of the workpiece 5 and can accordingly be difficult to form uniform void-free plated layers. In one particular example, the current density can be significantly higher near the junctions between the contact elements and the workpiece 5 than at points distant from these junctions, an effect referred to in the industry as the “terminal effect.” This can result in electroplated layers that (a) are not uniformly thick and/or (b) contain voids and/or (c) non-uniformly incorporating impurities or defects. Both of these characteristics tend to reduce the effectiveness and/or reliability of the devices formed from the workpiece 5.

### SUMMARY

The present invention is directed toward methods and systems for electrolytically processing microelectronic workpieces. One aspect of several embodiments of the invention includes electrolytically depositing conductive material on a microelectronic workpiece by applying current to the workpiece through an electrolytic fluid from one or more electrodes. The distribution of current in the electrolytic fluid is actively changed during the course of the process. For example, in one embodiment, the current is applied by a plurality of electrodes in a manner that can account for different plating characteristics at different portions of the workpiece, and the current applied to individual electrodes is changed to account for changes in behavior as the thickness of the conductive material on the workpiece increases. As a result, conductive materials such as copper are deposited on the workpiece at a uniform current density or other desired current density to provide a conductive layer having the desired properties. Several embodiments of the present invention accordingly apply the current to the individual electrodes to counteract the terminal effect between the contact elements and the workpiece. Additional embodiments of the invention compensate for irregularities in the seed layers or other aspects of single-wafer electrochemical deposition techniques to inhibit voids and produce plated layers with a desired thickness.

The current applied to the electrodes is varied in a variety of manners. For example, in one embodiment the current is varied such that the ratio of the current applied to one electrode relative to the currents provided by all the electrodes changes over time. This ratio has one value while features in a seed layer of the workpiece are filled, and another value while a blanket layer is applied to the filled features. In another arrangement, the current is applied such that the current density per unit area of the microelectronic workpiece varies by less than about ten percent of a 3σ value across the surface of the workpiece.

In still further embodiments, the current is varied in other manners. For example, in one embodiment the current is varied to create a domed or dished blanket layer on an initially flat seed layer, or a flat blanket layer on an initially domed or dished seed layer. In another embodiment, current is provided at an opposite polarity to at least one of the electrodes to either remove material from the workpiece or attract material that would otherwise attach to the workpiece, again, to form a conductive layer having a desired shape and/or uniformity.

### BRIEF DESCRIPTION OF THE DRAWINGS

FIG. 1 is a schematic diagram of an electroplating chamber in accordance with the prior art.

FIG. 2 is an isometric view of an electroprocessing machine having electroprocessing stations for processing microelectronic workpieces in accordance with an embodiment of the invention.

FIG. 3 is a cross-sectional view of an electroprocessing station having a processing chamber for use in an electroprocessing machine in accordance with an embodiment of the invention. Selected components in FIG. 3 are shown schematically.

FIG. 4 is an isometric view showing a cross-sectional portion of a processing chamber taken along line 4-4 of FIG. 8A.

FIGS. 5A-5D are cross-sectional views of a distributor for a processing chamber in accordance with an embodiment of the invention.

FIG. 6 is an isometric view showing a different cross-sectional portion of the processing chamber of FIG. 4 taken along line 6-6 of FIG. 8B.

FIG. 7A is an isometric view of an interface assembly for use in a processing chamber in accordance with an embodiment of the invention.

FIG. 7B is a cross-sectional view of the interface assembly of FIG. 7A.

FIGS. 8A and 8B are top plan views of a processing chamber that provide a reference for the isometric, cross-sectional views of FIGS. 4 and 6, respectively.

FIGS. 9A-9D are flow diagrams illustrating processes in accordance with embodiments of the invention.

FIG. 10A is a table illustrating predicted electrode currents as a function of initial seed layer thickness for instantaneously uniform deposition, simulating a multi-stage deposition process in accordance with an embodiment of the invention.

FIG. 10B is a graph illustrating the predicted electrode currents as a function of initial seed layer thickness based on the table of FIG. 10A.

FIG. 11 illustrates predicted electrode currents as a function of time for a multi-stage process in accordance with an embodiment of the invention.

FIG. 12 is a graphical comparison of film non-uniformity as a function of film thickness for an existing single-step plating process and a multi-stage process in accordance with an embodiment of the invention.

FIG. 13 is a graph of predicted current density as a function of location on a microelectronic workpiece for a multi-stage process in accordance with an embodiment of the invention.

FIG. 14 is a graph of predicted current density as a function of location on a microelectronic workpiece for an existing single-stage process.

FIG. 15 is a graph of experimentally determined initial and final conductive layer thicknesses for a microelectronic workpiece processed in accordance with an embodiment of the invention.

FIG. 16 is a graph illustrating experimentally determined initial and final thicknesses for a concave conductive layer deposited in accordance with an embodiment of the invention.

### DETAILED DESCRIPTION

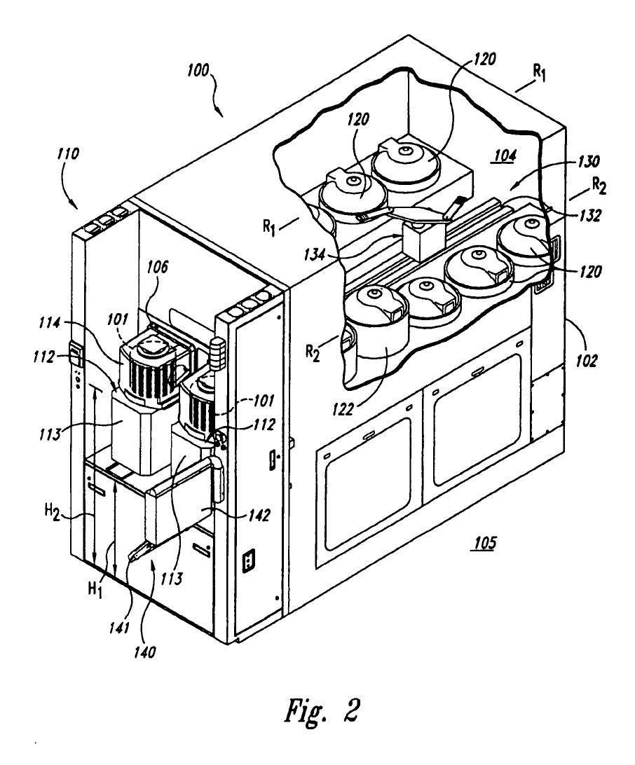

The following description discloses the details and features of several embodiments of electrochemical reaction vessels for use in electrochemical processing stations and integrated tools to process microelectronic workpieces. The term “microelectronic workpiece” is used throughout to include a workpiece formed from a substrate upon which and/or in which microelectronic circuits or components, data storage elements or layers, and/or micro-mechanical elements are fabricated. It will be appreciated that several of the details set forth below are provided to describe the following embodiments in a manner sufficient to enable a person skilled in the art to make and use the disclosed embodiments. Several of the details and advantages described below, however, may not be necessary to practice certain embodiments of the invention. Additionally, the invention can also include additional embodiments that are within the scope of the claims, but are not described in detail with respect to FIGS. 2-16.

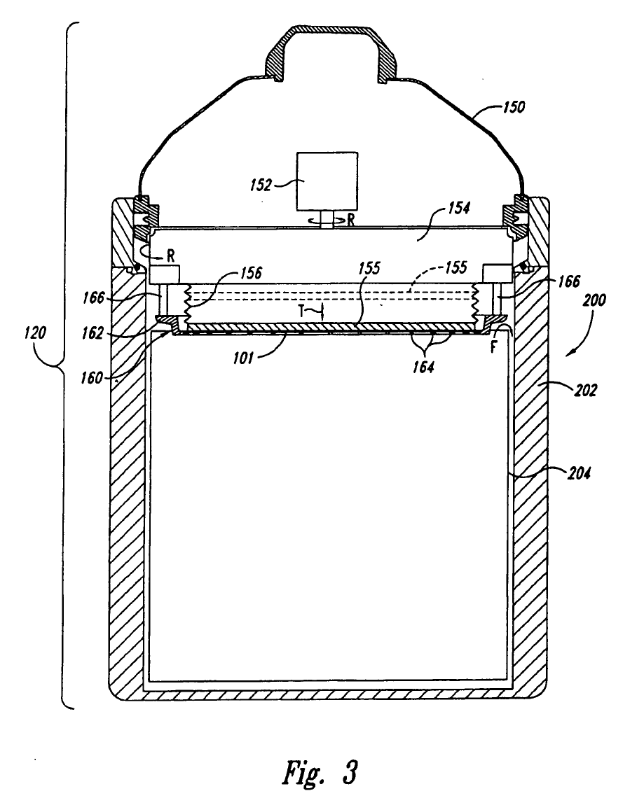

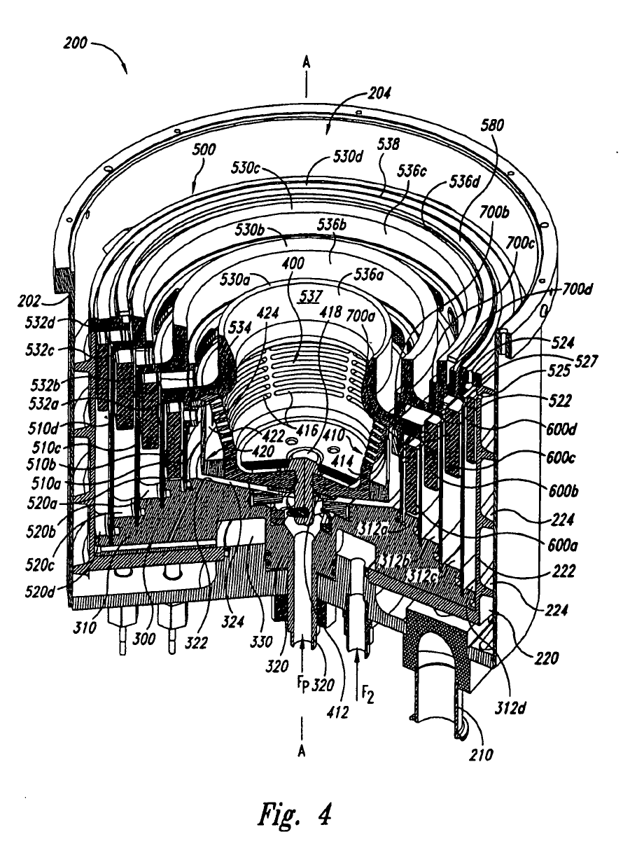

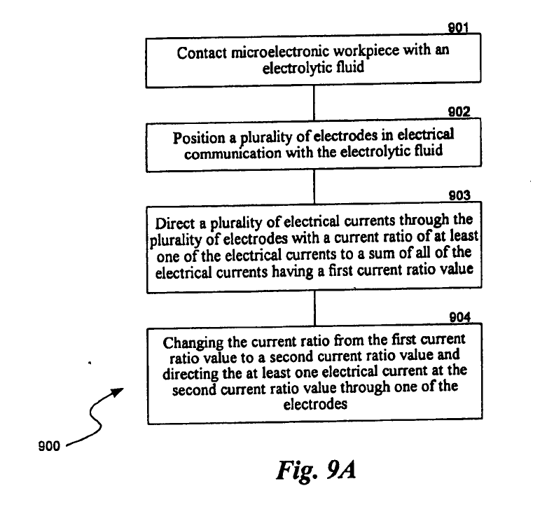

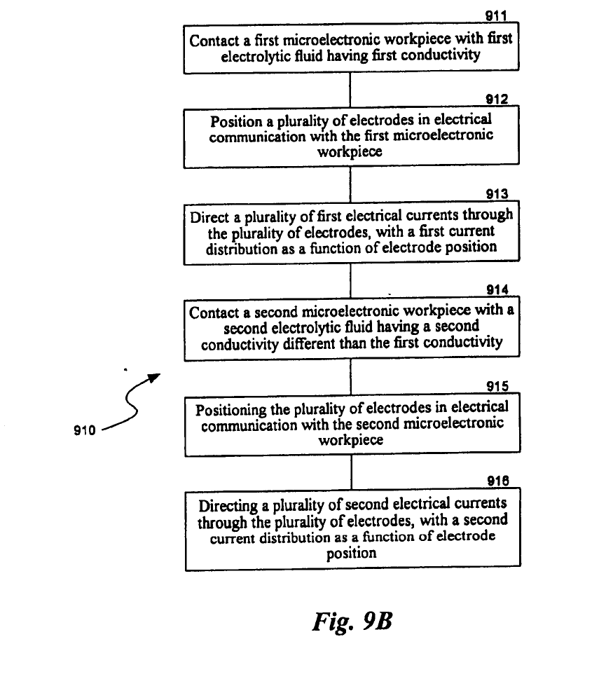

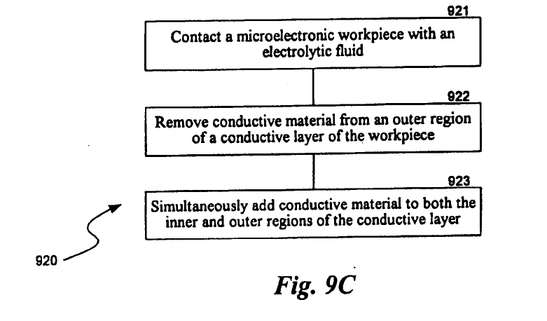

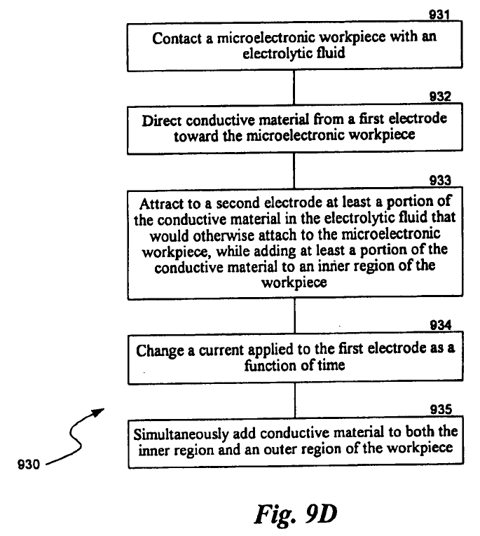

The operation and features of electrochemical reaction vessels are best understood in light of the environment and equipment in which they can be used to electrochemically process workpieces (e.g., electroplate and/or electropolish). As such, embodiments of integrated tools with processing stations having the electrochemical reaction vessels are initially described with reference to FIGS. 2 and 3 (Section A). The details and features of several embodiments of electrochemical reaction vessels and methods for mechanically controlling the electrochemical processing current during processing are then described with reference to FIGS. 4-8B (Section B). Further details of methods for electrically controlling the current during electrochemical processing are described with reference to FIGS. 9A-16 (Section C).

A. Selected Embodiments of Integrated Tools With Electrochemical Processing Stations

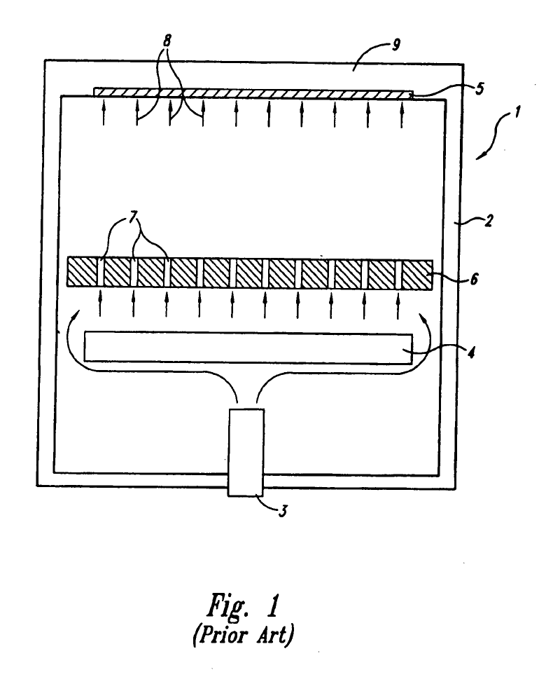

FIG. 2 is an isometric view of a system, such a processing machine 100, having an electrochemical processing station 120 in accordance with an embodiment of the invention. A portion of the processing machine 100 is shown in a cut-away view to illustrate selected internal components. In one aspect of this embodiment, the processing machine 100 includes a cabinet 102 having an interior region 104 defining an interior enclosure that is at least partially isolated from an exterior region 105. The cabinet 102 also includes a plurality of apertures 106 (only one shown in FIG. 1) through which microelectronic workpieces 101 can ingress and egress between the interior region 104 and a load/unload station 110.

In one embodiment, the load/unload station 110 has two container supports 112 that are each housed in a protective shroud 113. The container supports 112 are configured to position workpiece containers 114 relative to the apertures 106 in the cabinet 102. The workpiece containers 114 each house a plurality of microelectronic workpieces 101 in a “mini” clean environment for carrying a plurality of workpieces through other environments that are not at clean room standards. Each of the workpiece containers 114 is accessible from the interior region 104 of the cabinet 102 through the apertures 106.

In one embodiment, the processing machine 100 also includes a plurality of electrochemical processing stations 120 and a transfer device 130 in the interior region 104 of the cabinet 102. In one aspect of this embodiment, the processing machine 100 is a plating tool that also includes clean/etch capsules 122, electroless plating stations, annealing stations, and/or metrology stations.

The transfer device 130 includes a linear track 132 extending in a lengthwise direction of the interior region 104 between the processing stations. In one aspect of this embodiment, the transfer device 130 further includes a robot unit 134 carried by the track 132. In the particular embodiment shown in FIG. 2, a first set of processing stations is arranged along a first row R₁-R₁ and a second set of processing stations is arranged along a second row R₂-R₂. The linear track 132 extends between the first and second rows of processing stations, and the robot unit 134 can access any of the processing stations along the track 132.

In a further aspect of this embodiment, the processing machine 100 includes a controller 140 (such as a computer) that coordinates the activities of the load/unload station 110, the processing stations 120, and the transfer device 130. In a particular embodiment, the controller 140 includes an input device 141 (such as a keyboard), a graphical user interface 142 (such as an LCD screen) and a processor (not visible in FIG. 2). The controller 140 also includes a computer operable medium, such as a memory or a computer-readable medium (for example, a hard disk, floppy disk or CD). In one embodiment, the computer operable medium includes instructions for directing the operation of the load/unload station 110 and the transfer device 130 to move workpieces into and out of the processing stations 120. In one aspect of this embodiment, the computer operable medium also includes instructions for a controller 140 regulating the electrical current(s) applied to the workpieces processed in the processing stations 120, as described in greater detail below with reference to FIGS. 9A-16.

FIG. 3 illustrates an embodiment of an electrochemical-processing chamber 120 having a head assembly 150 and a processing chamber 200. The head assembly 150 includes a spin motor 152, a rotor 154 coupled to the spin motor 152, and a contact assembly 160 carried by the rotor 154. The rotor 154 can have a backing plate 155 and a seal 156. The backing plate 155 can move transverse to a workpiece 101 (arrow T) between a first position in which the backing plate 155 contacts a backside of the workpiece 101 (shown in solid lines in FIG. 3) and a second position in which it is spaced apart from the backside of the workpiece 101 (shown in broken lines in FIG. 3). The contact assembly 160 can have a support member 162, a plurality of contacts 164 carried by the support member 162, and a plurality of shafts 166 extending between the support member 162 and the rotor 154. The contacts 164 can be ring-type spring contacts or other types of contacts that are configured to engage a portion of the seed-layer on the workpiece 101. Commercially available head assemblies 150 and contact assemblies 160 can be used in the electroprocessing chamber 120. Particular suitable head assemblies 150 and contact assemblies 160 are disclosed in U.S. Pat. Nos. 6,228,232 and 6,080,691; and U.S. application Ser. Nos. 09/385,784; 09/386,803; 09/386,610; 09/386,197; 09/501,002; 09/733,608; and 09/804,696, all of which are herein incorporated by reference.

The processing chamber 200 includes an outer housing 202 (shown schematically in FIG. 3) and a reaction vessel 204 (also shown schematically in FIG. 3) in the housing 202. The reaction vessel 204 carries at least one electrode (not shown in FIG. 3) and directs a flow of electroprocessing solution to the workpiece 101. The electroprocessing solution, for example, can flow over a weir (arrow F) and into the external housing 202, which captures the electroprocessing solution and sends it back to a tank. Several embodiments of reaction vessels 204 are shown and described in detail with reference to FIGS. 4-8B.

In operation, the head assembly 150 holds the workpiece at a workpiece-processing site of the reaction vessel 204 so that at least a plating surface of the workpiece engages the electroprocessing solution. An electrical field is established in the solution by applying an electrical potential between the plating surface of the workpiece via the contact assembly 160 and one or more electrodes in the reaction vessel 204. For example, the contact assembly 160 can be biased with a negative potential with respect to the electrode(s) in the reaction vessel 204 to plate materials onto the workpiece. On the other hand, the contact assembly 160 can be biased with a positive potential with respect to the electrode(s) in the reaction vessel 204 to (a) de-plate or electropolish plated material from the workpiece or (b) deposit other materials (e.g., electrophoretic resist). In general, therefore, materials can be deposited. on or removed from the workpiece with the workpiece acting as a cathode or an anode depending upon the particular type of material used in the electrochemical process.

B. Selected Embodiments of Reaction Vessels For Use in Electrochemical Processing Chambers

FIGS. 4-8B illustrate several embodiments of reaction vessels 204 for use in the processing chamber 200. As explained above, the housing 202 carries the reaction vessel 204. The housing 202 can have a drain 210 for returning the processing fluid that flows out of the reaction vessel 204 to a storage tank, and a plurality of openings for receiving inlets and electrical fittings. The reaction vessel 204 can include an outer container 220 having an outer wall 222 spaced radially inwardly of the housing 202. The outer container 220 can also have a spiral spacer 224 between the outer wall 222 and the housing 202 to provide a spiral ramp (i.e., a helix) on which the processing fluid can flow downward to the bottom of the housing 202. The spiral ramp reduces the entrainment of gasses in the return fluid.

The particular embodiment of the reaction vessel 204 shown in FIG. 4 can include a distributor 300 for receiving a primary fluid flow Fₚ and a secondary fluid flow F₂, a primary flow guide 400 coupled to the distributor 300 to condition the primary fluid flow Fₚ, and a field shaping unit 500 coupled to the distributor 300 to contain the secondary flow F₂ in a manner that shapes the electrical field in the reaction vessel 204. The reaction vessel 204 can also include at least one electrode 600 in a compartment of the field shaping unit 500 and at least one filter or other type of interface member 700 carried by the field shaping unit 500 downstream from the electrode. The primary flow guide 400 can condition the primary flow Fₚ by projecting this flow radially inwardly relative to a common axis A-A, and a portion of the field shaping unit 500 directs the conditioned primary flow Fₚ toward the workpiece. In several embodiments, the primary flow passing through the primary flow guide 400 and the center of the field shaping unit 500 controls the mass transfer of processing solution at the surface of the workpiece. The field shaping unit 500 also defines the shape the electric field, and it can influence the mass transfer at the surface of the workpiece if the secondary flow passes through the field shaping unit. The rate at which the workpiece is rotated (typically from about 20 rpm to about 100 rpm) can also be used to influence the mass transfer at the surface of the workpiece.

The reaction vessel 204 can also have other configurations of components to guide the primary flow Fₚ and the secondary flow F₂ through the processing chamber 200. For example, in one embodiment, the reaction vessel 204 includes a shield 580 having a central opening surrounded by a ring-shaped, solid portion that at least limits contact between the fluid flow and the peripheral region of the workpiece 101 (FIG. 3). In one aspect of this embodiment, the shield 580 is removed entirely or replaced with another shield having a larger or smaller central opening to control the fluid flow passing adjacent to the peripheral region of the workpiece 101 and to influence the electrical field in the peripheral region. In a further aspect of this embodiment, the vertical separation between the shield 580 and the workpiece 101 is also adjusted to control the interaction between the fluid and the workpiece 101. In one embodiment, the reaction vessel 204 also includes a diffuser (generally similar to that shown in FIG. 1) positioned in the fluid flow. The porosity/hole pattern of the diffuser is selected to further control the interaction between the fluid/electrical field and the workpiece 101.

In still further embodiments, the reaction vessel 204 has other configurations. The reaction vessel 204, for example, may not have a distributor in the processing chamber, but rather separate fluid lines with individual flows can be coupled to the vessel 204 to provide a desired distribution of fluid through the primary flow guide 400 and the field shaping unit. For example, the reaction vessel 204 can have a first outlet in the outer container 220 for introducing the primary flow into the reaction vessel and a second outlet in the outer container for introducing the secondary flow into the reaction vessel 204. Each of these components is explained in more detail below.

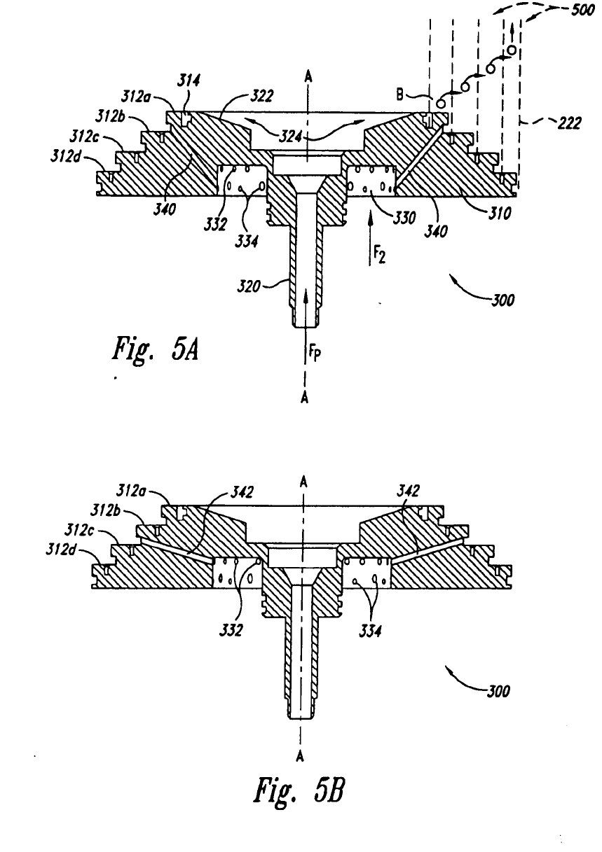

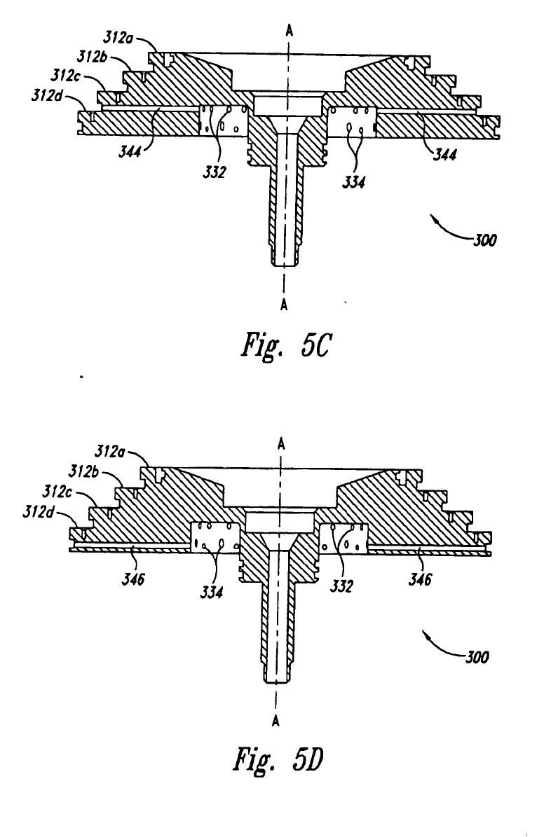

FIGS. 5A-5D illustrate an embodiment of the distributor 300 for directing the primary fluid flow to the primary flow guide 400 and the secondary fluid flow to the field shaping unit 500. Referring to FIG. 5A, the distributor 300 can include a body 310 having a plurality of annular steps 312 (identified individually by reference numbers 312a-d) and annular grooves 314 in the steps 312. The outermost step 312d is radially inward of the outer wall 222 (shown in broken lines) of the outer container 220 (FIG. 4), and each of the interior steps 312a-c can carry an annular wall (shown in broken lines) of the field shaping unit 500 in a corresponding groove 314. The distributor 300 can also include a first inlet 320 for receiving the primary flow Fₚ and a plenum 330 for receiving the secondary flow F₂. The first inlet 320 can have an inclined, annular cavity 322 to form a passageway 324 (best shown in FIG. 4) for directing the primary fluid flow Fp under the primary flow guide 400. The distributor 300 can also have a plurality of upper orifices 332 along an upper part of the plenum 330 and a plurality of lower orifices 334 along a lower part of the plenum 330. As explained in more detail below, the upper and lower orifices are open to channels through the body 310 to distribute the secondary flow F₂ to the risers of the steps 312. The distributor 300 can also have other configurations, such as a “step-less” disk or non-circular shapes.

FIGS. 5A-5D further illustrate one configuration of channels through the body 310 of the distributor 300. Referring to FIG. 5A, a number of first channels 340 extend from some of the lower orifices 334 to openings at the riser of the first step 312a. FIG. 5B shows a number of second channels 342 extending from the upper orifices 332 to openings at the riser of the second step 312b, and FIG. 5C shows a number of third channels 344 extending from the upper orifices 332 to openings at the riser of the third step 312c. Similarly, FIG. 5D illustrates a number of fourth channels 346 extending from the lower orifices 334 to the riser of the fourth step 312d.

The particular embodiment of the channels 340-346 in FIGS. 5A-5D are configured to transport bubbles that collect in the plenum 330 radially outward as far as practical so that these bubbles can be captured and removed from the secondary flow F₂. This is beneficial because the field shaping unit 500 removes bubbles from the secondary flow F₂ by sequentially transporting the bubbles radially outwardly through electrode compartments. For example, a bubble B in the compartment above the first step 312a can sequentially cascade through the compartments over the second and third steps 312b-c, and then be removed from the compartment above the fourth step 312d. The first channel 340 (FIG. 5A) accordingly carries fluid from the lower orifices 334 where bubbles are less likely to collect to reduce the amount of gas that needs to cascade from the inner compartment above the first step 312a all the way out to the outer compartment. The bubbles in the secondary flow F₂ are more likely to collect at the top of the plenum 330 before passing through the channels 340-346. The upper orifices 332 are accordingly coupled to the second channel 342 and the third channel 344 to deliver these bubbles outward beyond the first step 312a so that they do not need to cascade through so many compartments. In this embodiment, the upper orifices 332 are not connected to the fourth channels 346 because this would create a channel that inclines downwardly from the common axis such that it may conflict with the groove 314 in the third step 312c. Thus, the fourth channel 346 extends from the lower orifices 334 to the fourth step 312d.

Referring again to FIG. 4, the primary flow guide 400 receives the primary fluid flow Fₚ via the first inlet 320 of the distributor 300. In one embodiment, the primary flow guide 400 includes an inner baffle 410 and an outer baffle 420. The inner baffle can have a base 412 and a wall 414 projecting upward and radially outward from the base 412. The wall 414, for example, can have an inverted frusto-conical shape and a plurality of apertures 416. The apertures 416 can be holes, elongated slots or other types of openings. In the illustrated embodiment, the apertures 416 are annularly extending radial slots that slant upward relative to the common axis to project the primary flow radially inward and upward relative to the common axis along a plurality of diametrically opposed vectors. The inner baffle 410 can also includes a locking member 418 that couples the inner baffle 410 to the distributor 300.

The outer baffle 420 can include an outer wall 422 with a plurality of apertures 424. In this embodiment, the apertures 424 are elongated slots extending in a direction transverse to the apertures 416 of the inner baffle 410. The primary flow Fₚ flows through (a) the first inlet 320, (b) the passageway 324 under the base 412 of the inner baffle 410, (c) the apertures 424 of the outer baffle 420, and then (d) the apertures 416 of the inner baffle 410. The combination of the outer baffle 420 and the inner baffle 410 conditions the direction of the flow at the exit of the apertures 416 in the inner baffle 410. The primary flow guide 400 can thus project the primary flow along diametrically opposed vectors that are inclined upward relative to the common axis to create a fluid flow that has a highly uniform velocity. In alternate embodiments, the apertures 416 do not slant upward relative to the common axis such that they can project the primary flow normal, or even downward, relative to the common axis.

FIG. 4 also illustrates an embodiment of the field shaping unit 500 that receives the primary fluid flow Fₚ downstream from the primary flow guide 400. The field shaping unit 500 also contains the second fluid flow F₂ and shapes the electrical field within the reaction vessel 204. In this embodiment, the field shaping unit 500 has a compartment structure with a plurality of walls 510 (identified individually by reference numbers 510a-d) that define electrode compartments 520 (identified individually by reference numbers 520a-d). The walls 510 can be annular skirts or dividers, and they can be received in one of the annular grooves 314 in the distributor 300. In one embodiment, the walls 510 are not fixed to the distributor 300 so that the field shaping unit 500 can be quickly removed from the distributor 300. This allows easy access to the electrode compartments 520 and/or quick removal of the field shaping unit 500 to change the shape of the electric field.

The field shaping unit 500 can have at least one wall 510 outward from the primary flow guide 400 to prevent the primary flow Fₚ from contacting an electrode. In the particular embodiment shown in FIG. 4, the field shaping unit 500 has a first electrode compartment 520a defined by a first wall 510a and a second wall 510b, a second electrode compartment 520b defined by the second wall 510b and a third wall 510c, a third electrode compartment 520c defined by the third wall 510c and a fourth wall 510d, and a fourth electrode compartment 520d defined by the fourth wall 510d and the outer wall 222 of the container 220. The walls 510a-d of this embodiment are concentric annular dividers that define annular electrode compartments 520a-d. Alternate embodiments of the field shaping unit can have walls with different configurations to create non-annular electrode compartments and/or each electrode compartment can be further divided into cells. The second-fourth walls 510b-d can also include holes 522 for allowing bubbles in the first-third electrode compartments 520a-c to “cascade” radially outward to the next outward electrode compartment 520 as explained above with respect to FIGS. 5A-5D. The bubbles can then exit the fourth electrode compartment 520d through an exit hole 525 through the outer wall 222. In an alternate embodiment, the bubbles can exit through an exit hole 524.

The electrode compartments 520 provide electrically discrete compartments to house an electrode assembly having at least one electrode and generally two or more electrodes 600 (identified individually by reference numbers 600a-d). The electrodes 600 can be annular members (e.g., annular rings or arcuate sections) that are configured to fit within annular electrode compartments, or they can have other shapes appropriate for the particular workpiece (e.g., rectilinear). In the illustrated embodiment, for example, the electrode assembly includes a first annular electrode 600a in the first electrode compartment 520a, a second annular electrode 600b in the second electrode compartment 520b, a third annular electrode 600c in the third electrode compartment 520c, and a fourth annular electrode 600d in the fourth electrode compartment 520d. As explained in U.S. application Ser. Nos. 60/206,661, 09/845,505, and 09/804,697, all of which are incorporated herein by reference, each of the electrodes 600a-d can be biased with the same or different potentials with respect to the workpiece to control the current density across the surface of the workpiece. In alternate embodiments, the electrodes 600 can be non-circular shapes or sections of other shapes.

The field shaping unit 500 can also include a virtual electrode unit coupled to the walls 510 of the compartment assembly for individually shaping the electrical fields produced by the electrodes 600. In the particular embodiment illustrated in FIG. 4, the virtual electrode unit includes first-fourth partitions 530a-530d, respectively. The first partition 530a can have a first section 532a coupled to the second wall 510b, a skirt 534 depending downward above the first wall 510a,and a lip 536a projecting upwardly. The lip 536a has an interior surface 537 that directs the primary flow Fₚ exiting from the primary flow guide 400. The second partition 530b can have a first section 532b coupled to the third wall 510c and a lip 536b projecting upward from the first section 532b, the third partition 530c can have a first section 532c coupled to the fourth wall 510d and a lip 536c projecting upward from the first section 532c, and the fourth partition 530d can have a first section 532d carried by the outer wall 222 of the container 220 and a lip 536d projecting upward from the first section 532d. The fourth partition 530d may not be connected to the outer wall 222 so that the field shaping unit 500 can be quickly removed from the vessel 204 by simply lifting the virtual electrode unit. The interface between the fourth partition 530d and the outer wall 222 is sealed by a seal 527 to inhibit both the fluid and the electrical current from leaking out of the fourth electrode compartment 520d. The seal 527 can be a lip seal. Additionally, each of the sections 532a-d can be lateral sections extending transverse to the common axis.

The individual partitions 530a-d can be machined from or molded into a single piece of dielectric material, or they can be individual dielectric members that are welded together. In alternate embodiments, the individual partitions 530a-d are not attached to each other and/or they can have different configurations. In the particular embodiment shown in FIG. 4, the partitions 530a-d are annular horizontal members, and each of the lips 536a-d are annular vertical members arranged concentrically about the common axis.

The walls 510 and the partitions 530a-d are generally dielectric materials that contain the second flow F₂ of the processing solution for shaping the electric fields generated by the electrodes 600a-d. The second flow F₂, for example, can pass (a) through each of the electrode compartments 520a-d, (b) between the individual partitions 530a-d, and then (c) upward through the annular openings between the lips 536a-d. In this embodiment, the secondary flow F₂ through the first electrode compartment 520a can join the primary flow Fₚ in an antechamber just before the primary flow guide 400, and the secondary flow through the second-fourth electrode compartments 520b-d can join the primary flow Fₚ beyond the top edges of the lips 536a-d. The flow of electroprocessing solution then flows over a shield weir attached at rim 538 and into the gap between the housing 202 and the outer wall 222 of the container 220 as disclosed in International Application No. PCT/US00/10120, incorporated herein by reference. The fluid in the secondary flow F₂ can be prevented from flowing out of the electrode compartments 520a-d to join the primary flow Fₚ while still allowing electrical current to pass from the electrodes 600 to the primary flow. In this alternate embodiment, the secondary flow F₂ can exit the reaction vessel 204 through the holes 522 in the walls 510 and the hole 525 in the outer wall 222. In still additional embodiments in which the fluid of the secondary flow does not join the primary flow, a duct can be coupled to the exit hole 525 in the outer wall 222 so that a return flow of the secondary flow passing out of the field shaping unit 500 does not mix with the return flow of the primary flow passing down the spiral ramp outside of the outer wall 222.The field shaping unit 500 can have other configurations that are different than the embodiment shown in FIG. 4. For example, the electrode compartment assembly can have only a single wall 510 defining a single electrode compartment 520, and the reaction vessel 204 can include only a single electrode 600. The field shaping unit of either embodiment still separates the primary and secondary flows so that the primary flow does not engage the electrode, and thus it shields the workpiece from the single electrode. One advantage of shielding the workpiece from the electrodes 600a-d is that the electrodes can accordingly be much larger than they could be without the field shaping unit because the size of the electrodes does not have an effect on the electrical field presented to the workpiece. This is particularly useful in situations that use consumable electrodes because increasing the size of the electrodes prolongs the life of each electrode, which reduces downtime for servicing and replacing electrodes.

An embodiment of reaction vessel 204 shown in FIG. 4 can accordingly have a first conduit system for conditioning and directing the primary fluid flow Fₚ to the workpiece, and a second conduit system for conditioning and directing the secondary fluid flow F₂. The first conduit system, for example, can include the inlet 320 of the distributor 300; the channel 324 between the base 412 of the primary flow guide 400 and the inclined cavity 322 of the distributor 300; a plenum between the wall 422 of the outer baffle 420 and the first wall 510a of the field shaping unit 500; the primary flow guide 400; and the interior surface 537 of the first lip 536a. The first conduit system conditions the direction of the primary fluid flow Fₚ by passing it through the primary flow guide 400 and along the interior surface 537 so that the velocity of the primary flow Fₚ normal to the workpiece is at least substantially uniform across the surface of the workpiece. The primary flow Fₚ and the rotation of the workpiece can accordingly be controlled to influence the mass transfer of electroprocessing medium at the workpiece.

The second conduit system, for example, can include the plenum 330 and the channels 340-346 of the distributor 300, the walls 510 of the field shaping unit 500, and the partitions 530 of the field shaping unit 500. The secondary flow F₂ contacts the electrodes 600 to establish individual electrical fields in the field shaping unit 500 that are electrically coupled to the primary flow Fₚ. The field shaping unit 500, for example, separates the individual electrical fields created by the electrodes 600a-d to create “virtual electrodes” at the top of the openings defined by the lips 536a-d of the partitions. In this particular embodiment, the central opening inside the first lip 536a defines a first virtual electrode, the annular opening between the first and second lips 536a-b defines a second virtual electrode, the annular opening between the second and third lips 536b-c defines a third virtual electrode, and the annular opening between the third and fourth lips 536c-d defines a fourth virtual electrode. These are “virtual electrodes” because the field shaping unit 500 shapes the individual electrical fields of the actual electrodes 600a-d so that the effect of the electrodes 600a-d acts as if they are placed between the top edges of the lips 536a-d. This allows the actual electrodes 600a-d to be isolated from the primary fluid flow, which can provide several benefits as explained in more detail below.

An additional embodiment of the processing chamber 200 includes at least one interface member 700 (identified individually by reference numbers 700a-d) for further conditioning the secondary flow F₂ of electroprocessing solution. The interface members 700, for example, can be filters that capture particles in the secondary flow that were generated by the electrodes (i.e., anodes) or other sources of particles. The filter-type interface members 700 can also inhibit bubbles in the secondary flow F₂ from passing into the primary flow Fₚ of electroprocessing solution. This effectively forces the bubbles to pass radially outwardly through the holes 522 in the walls 510 of the field shaping unit 500. In alternate embodiments, the interface members 700 can be ion-membranes that allow ions in the secondary flow F₂ to pass through the interface members 700. The ion-membrane interface members 700 can be selected to (a) allow the fluid of the electroprocessing solution and ions to pass through the interface member 700, or (b) allow only the desired ions to pass through the interface member such that the fluid itself is prevented from passing beyond the ion-membrane.

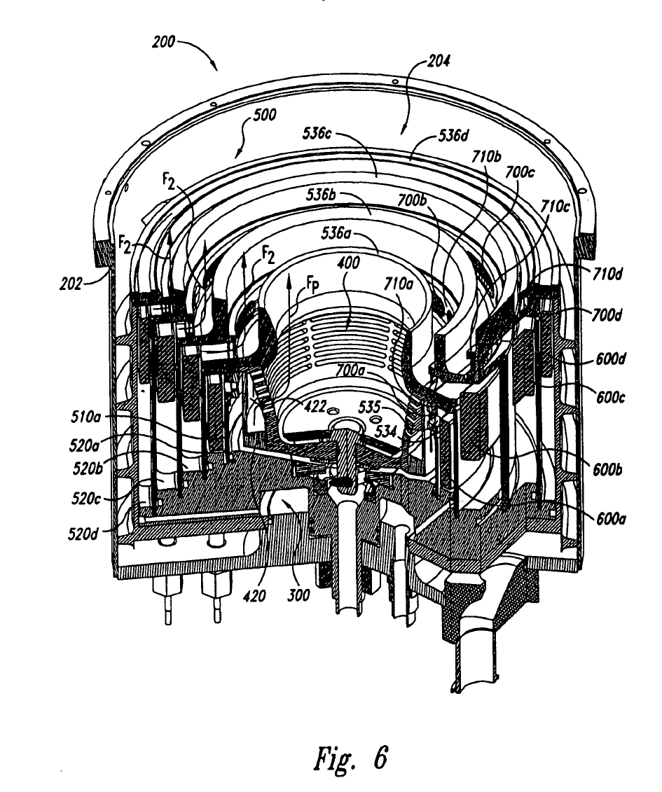

FIG. 6 is another isometric view of the reaction vessel 204 of FIG. 4 showing a cross-sectional portion taken along a different cross-section. More specifically, the cross-section of FIG. 4 is shown in FIG. 8A and the cross-section of FIG. 6 is shown in FIG. 8B. Returning now to FIG. 6, this illustration further shows one embodiment for configuring a plurality of interface members 700a-d relative to the partitions 530a-d of the field shaping unit 500. A first interface member 700a can be attached to the skirt 534 of the first partition 530a so that a first portion of the secondary flow F₂ flows past the first electrode 600a,through an opening 535 in the skirt 534, and then to the first interface member 700a. Another portion of the secondary flow F₂ can flow past the second electrode 600b to the second interface member 700b. Similarly, portions of the secondary flow F₂ can flow past the third and fourth electrodes 600c-d to the third and fourth interface members 700c-d.

When the interface members 700a-d are filters or ion-membranes that allow the fluid in the secondary flow F₂ to pass through the interface members 700a-d, the secondary flow F₂ joins the primary fluid flow Fₚ. The portion of the secondary flow F₂ in the first electrode compartment 520a can pass through the opening 535 in the skirt 534 and the first interface member 700a, and then into a plenum between the first wall 510a and the outer wall 422 of the baffle 420. This portion of the secondary flow F₂ accordingly joins the primary flow Fₚ and passes through the primary flow guide 400. The other portions of the secondary flow F₂ in this particular embodiment pass through the second-fourth electrode compartments 520b-d and then through the annular openings between the lips 536a-d. The second-fourth interface members 700b-d can accordingly be attached to the field shaping unit 500 downstream from the second-fourth electrodes 600b-d.

In the particular embodiment shown in FIG. 6, the second interface member 700b is positioned vertically between the first and second partitions 530a-b, the third interface member 700c is positioned vertically between the second and third partitions 530b-c, and the fourth interface member 700d is positioned vertically between the third and fourth partitions 530c-d. The interface assemblies 710a-d are generally installed vertically, or at least at an upwardly inclined angle relative to horizontal, to force the bubbles to rise so that they can escape through the holes 522 in the walls 510a-d (FIG. 4). This prevents aggregations of bubbles that could potentially disrupt the electrical field from an individual electrode.

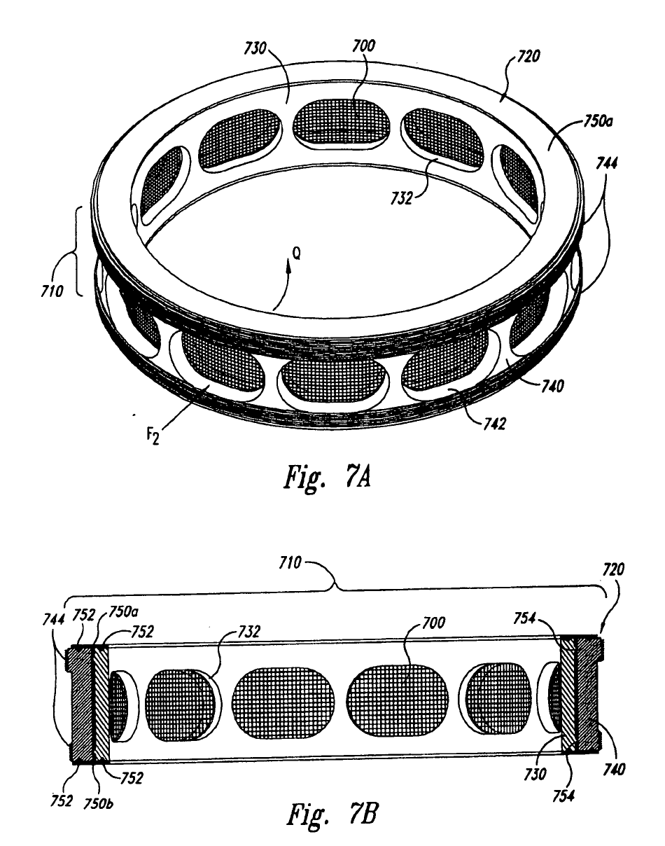

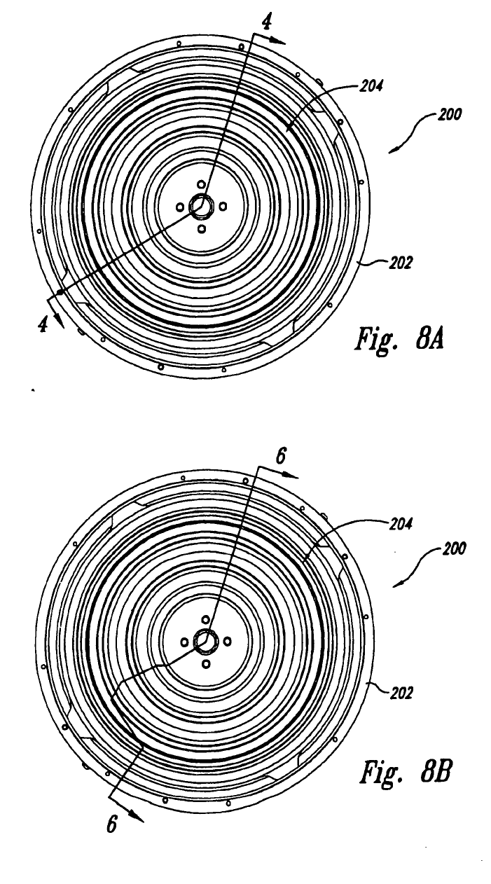

FIGS. 7A and 7B illustrate an interface assembly 710 for mounting the interface members 700 to the field shaping unit 500 in accordance with an embodiment of the invention. The interface assembly 710 can include an annular interface member 700 and a fixture 720 for holding the interface member 700. The fixture 720 can include a first frame 730 having a plurality of openings 732 and a second frame 740 having a plurality of openings 742 (best shown in FIG. 7A). The holes 732 in the first frame can be aligned with the holes 742 in the second frame 740. The second frame can further include a plurality of annular teeth 744 extending around the perimeter of the second frame. It will be appreciated that the teeth 744 can alternatively extend in a different direction on the exterior surface of the second frame 740 in other embodiments, but the teeth 744 generally extend around the perimeter of the second frame 740 in a top annular band and a lower annular band to provide annular seals with the partitions 536a-d (FIG. 6). The interface member 700 can be pressed between the first frame 730 and the second frame 740 to securely hold the interface member 700 in place. The interface assembly 710 can also include a top band 750a extending around the top of the frames 730 and 740 and a bottom band 750b extending around the bottom of the frames 730 and 740. The top and bottom bands 750a-b can be welded to the frames 730 and 740 by annular welds 752. Additionally, the first and second frames 730 and 740 can be welded to each other by welds 754. It will be appreciated that the interface assembly 710 can have several different embodiments that are defined by the configuration of the field shaping unit 500 (FIG. 6) and the particular configuration of the electrode compartments 520a-d (FIG. 6).

When the interface member 700 is a filter material that allows the secondary flow F₂ of electroprocessing solution to pass through the holes 732 in the first frame 730, the post-filtered portion of the solution continues along a path (arrow Q) to join the primary fluid flow Fₚ as described above. One suitable material for a filter-type interface member 700 is POREX®, which is a porous plastic that filters particles to prevent them from passing through the interface member. In plating systems that use consumable anodes (e.g., phosphorized copper or nickel sulfamate), the interface member 700 can prevent the particles generated by the anodes from reaching the plating surface of the workpiece.

In alternate embodiments in which the interface member 700 is an ion-membrane, the interface member 700 can be permeable to preferred ions to allow these ions to pass through the interface member 700 and into the primary fluid flow Fₚ. One suitable ion-membrane is NAFION® perfluorinated membranes manufactured by DuPont®. Other suitable types of ion-membranes for plating can be polymers that are permeable to many cations, but reject anions and non-polar species. It will be appreciated that in electropolishing applications, the interface member 700 may be selected to be permeable to anions, but reject cations and non-polar species. The preferred ions can be transferred through the ion-membrane interface member 700 by a driving force, such as a difference in concentration of ions on either side of the membrane, a difference in electrical potential, or hydrostatic pressure.

Using an ion-membrane that prevents the fluid of the electroprocessing solution from passing through the interface member 700 allows the electrical current to pass through the interface member while filtering out particles, organic additives and bubbles in the fluid. For example, in plating applications in which the interface member 700 is permeable to cations, the primary fluid flow Fₚ can be a catholyte and the secondary fluid flow F₂ can be a separate anolyte because these fluids do not mix in this embodiment. A benefit of having separate anolyte and catholyte fluid flows is that it eliminates the consumption of additives at the anodes and thus the need to replenish the additives as often. Additionally, this feature combined with the “virtual electrode” aspect of the reaction vessel 204 reduces the need to “burn-in” anodes for insuring a consistent black film over the anodes for predictable current distribution because the current distribution is controlled by the configuration of the field shaping unit 500. Another advantage is that it also eliminates the need to have a predictable consumption of additives in the secondary flow F₂ because the additives to the secondary flow F₂ do not effect the primary fluid flow Fₚ when the two fluids are separated from each other.

In another embodiment, the geometry of the reaction vessel 204 described above with reference to FIGS. 3-8B is adjusted as the microelectronic workpiece 101 is processed to actively control the current distribution at the microelectronic workpiece 101 as a function of time. For example, in one aspect of this embodiment, the distance between the microelectronic workpiece 101 and the electrodes 600a-d and/or the shield 580 is adjusted while current is passing through the electroprocessing fluid. The distance is changed by moving the microelectronic workpiece 101, the electrodes 600a-d, and/or the shield 580 toward and away from each other.

In other embodiments, other methods are used to adjust the geometry of the reaction vessel 204 during proessing. For example, in one embodiment, the shield 580 (FIG. 4) has an adjustable diaphragm arrangement in which the central opening can change diameter, much like the aperture of a camera. In another embodiment, the distance between the shield 580 and the microelectronic workpiece 101 is adjusted by moving the shield 580 and/or the microelectronic workpiece 101 toward and/or away from each other. For example, the shielding provided to the periphery of the microelectronic workpiece 101 can be reduced during processing by increasing the distance between the workpiece 101 and the shield 580. In yet another embodiment, the openings in the diffuser (positioned between the electrodes 600a-d and the microelectronic workpiece 101) are each individually adjustable to change the flow distribution and/or the overall flow rate of electroprocessing fluid. For example, peripheral openings in the diffuser can be selectively closed or opened to increase or decrease, respectively, the shielding provided to the peripheral region of the workpiece 101. In still further embodiments, the geometry of the reaction vessel is altered during processing by other methods and/or mechanisms.

In any of the foregoing embodiments, mechanical changes to the geometry of the reaction vessel 204 change the distribution of current at the microelectronic workpiece 101 during processing. In other embodiments, described below in Section C, the current distribution is changed by changing the current applied to the electrodes 600a-d. The effects of actively changing the current distribution during processing, by mechanical and/or electrical techniques, are also described in greater detail below in Section C.

C. Method of Selecting and Applying Electrical Currents to Electrodes in Reaction Vessels

FIGS. 9A-9D illustrate processes that can be completed with the apparatuses described above with reference to FIGS. 2-8B by selectively adjusting the currents applied to multiple electrodes in processing chambers, for example, to adjust the current distribution in the electrolytic fluid within the processing chambers. For example, FIG. 9A illustrates a process 900 that includes contacting a microelectronic workpiece with an electrolytic fluid (process portion 901) and positioning a plurality of electrodes in electrical communication with the electrolytic fluid (process portion 902). The process 900 can further include directing a plurality of electrical currents through the plurality of electrodes and changing at least one of the currents in a selected manner during the process. For example, a current ratio of at least one of the electrical currents to a sum of all of the electrical currents can initially have a first current ratio value (process portion 903). In process portion 904, the current ratio is changed from the first current ratio value to a second current ratio value, and the at least one electrical current is directed at the second current ratio value through one of the electrodes.

In one embodiment, the current ratio is adjusted between at least two electrodes, and in another embodiment, the current ratio is adjusted over four electrodes. In a further embodiment, the current ratio is adjusted to maintain a current density across the workpiece that varies by less than ten percent of the 3-σ deviation level of a standard distribution curve. In other embodiments, the variation is less than five percent of the 3-σ level. In yet a further embodiment, the first current ratio value is used while features in a conductive layer of the workpiece are filled, and the second current ratio value is used while a blanket layer is applied to the filled features.

In another embodiment, the current distribution over a plurality of electrodes is adjusted to account for different electrolytic fluids having different conductivities. For example, as shown in FIG. 9B, a process 910 includes contacting a first microelectronic workpiece with a first electrolytic fluid having a first conductivity (process portion 911) and positioning a plurality of electrodes in electrical communication with the first microelectronic workpiece (process portion 912). An embodiment of the process 910 further includes directing a plurality of first electrical currents through the plurality of electrodes, with a first current distribution as a function of electrode position (process portion 913). In process portion 914, a second microelectronic workpiece is placed in contact with a second electrolytic fluid having a second conductivity different than the first conductivity. The process 910 further includes positioning the plurality of electrodes in electrical communication with the second microelectronic workpiece (process portion 915) and directing a plurality of second electrical currents through the plurality of electrodes, with a second current distribution as a function of electrode position (process portion 916).

In other embodiments, the current applied to the electrodes is used to remove conductive material from the workpiece, and/or thieve conductive material that would otherwise attach to the workpiece. For example, as shown in FIG. 9C, a process 920 includes contacting a microelectronic workpiece with an electrolytic fluid (process portion 921), removing conductive material from an outer region of a conductive layer of the workpiece (process portion 922), and then simultaneously adding conductive material to both the inner and outer regions of the conductive layer (process portion 923). In another embodiment, shown in FIG. 9D, a process 930 includes contacting the workpiece with an electrolytic fluid (process portion 931) and directing conductive material from a first electrode toward the microelectronic workpiece (process portion 932). The process 930 further includes attracting to a second electrode at least a portion of the conductive material in the electrolytic fluid that would otherwise attach to the workpiece, while adding at least a portion of the conductive material to an inner region of the workpiece (process portion 933). In one aspect of this embodiment, the process 930 further includes changing a current applied to the first electrode as a function of time (process portion 934) and then simultaneously adding conductive material to both the inner region and the outer region of the workpiece (process portion 935).

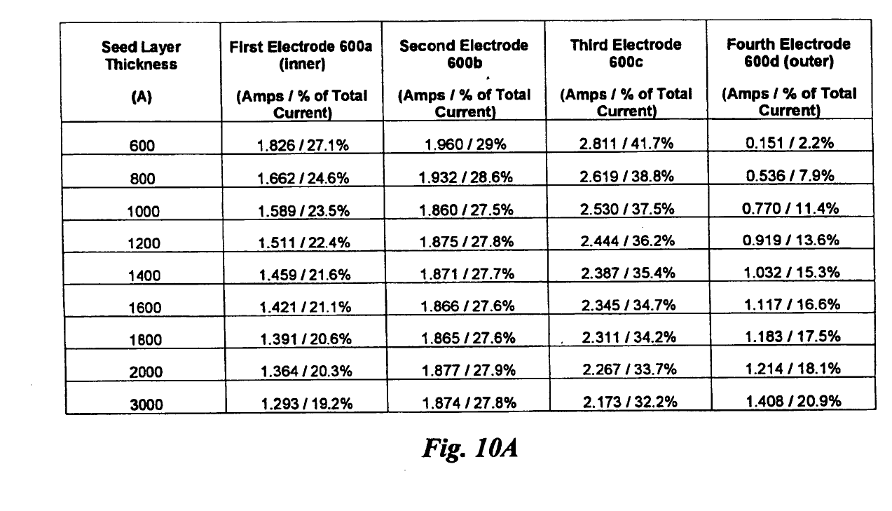

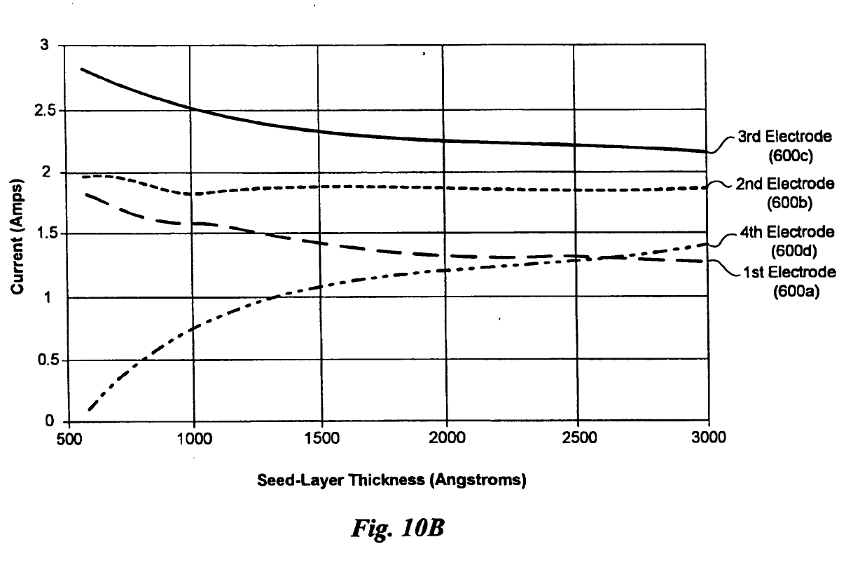

FIGS. 10A-16 illustrate analytical predictions and experimental results for plating conductive materials on microelectronic workpieces in accordance with several embodiments of the invention that can use multi-electrode processing chambers generally similar to those described above with reference to FIGS. 2-8. The examples described below relate to plating copper blanket layers on copper seed layers, but are also applicable to other materials and other plating operations. The methods are further applicable to material removal processes.

FIG. 10A illustrates a table of predicted current levels for each of four electrodes 600a-d (FIG. 4) as a function of initial seed layer thickness for a 200 mm workpiece. The predicted current levels are selected to produce a total current in each case of about 6.5 amps, and an instantaneously uniform current density (i.e., a uniform current per square centimeter of workpiece surface area) across the workpiece 101 (FIG. 3). Also shown in FIG. 10A for each initial seed layer thickness is the percentage of the total current applied to the workpiece 101 contributed by each electrode. FIG. 10B is a graphical illustration of the current levels for each electrode as a function of the initial seed layer thickness.

Referring now to FIGS. 10A and 10B, the percentage of the total current applied to the inner three electrodes (600a-c) tends to drop as the initial seed layer thickness increases. The percentage of the total current applied to the outermost electrode (600d) tends to increase as the initial seed layer thickness increases. It is believed that this result is due to the decreasing significance of the terminal effect as the seed layer thickness increases. For example, compared to a thick seed layer, a relatively thin seed layer will have a higher resistivity and accordingly electrical current will be concentrated near the contacts around the periphery of the workpiece 101. This will result in higher plating rates near the contacts than at the center of thin seed layers. Thus, the current applied to the outermost electrode can be lower than that applied to the inner electrodes to counteract the terminal effect If the seed layer is relatively thick, it will have a lower resistivity, and, all other variables being equal, the current density will tend to be more uniform over the surface of the workpiece 101. Accordingly, FIGS. 10A and 10B indicate that by changing the percentage of the current passing through each electrode as the seed layer thickens, a uniform current density over the surface of the workpiece 101 is obtained.

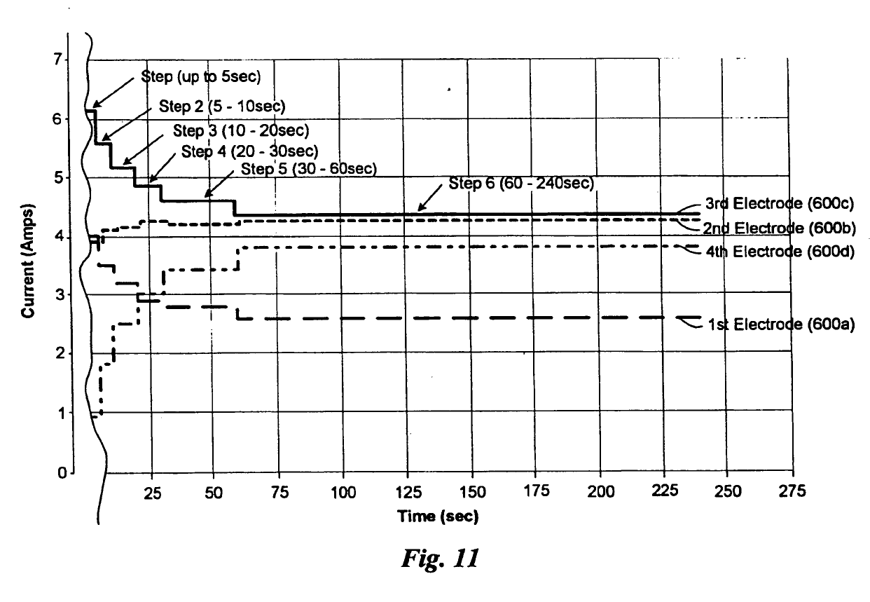

The results described above with reference to FIGS. 10A and 10B are somewhat simplified from an actual deposition process in that different starting seed layer thicknesses are used to simulate a buildup of conductive material on a given seed layer. For example, the predicted current levels for a 3,000 Å seed layer provide an indication of the current levels that would be required after 2,400 Å of conductive material have been built up on a 600 Å seed layer. This is somewhat simplified from the actual case in that slight non-uniformities that may tend to form during each step of the deposition process may not be accounted for. FIG. 11, described below, illustrates predicted results that account for at least a portion of this simplification.

FIG. 11 illustrates predicted current levels as a function of time applied to each of four electrodes 600a-d in a process that begins with a 1000 Å thick seed layer on a 300 mm workpiece, and ends with a 1 micron thick blanket layer. The current levels applied to each electrode 600a-d change in six discrete stages. As expected, (based on the results of FIGS. 10A and 10B) the current applied to the innermost electrode 600a tends to decrease over time and the current applied to the outermost electrode 600d tends to increase over time. The predicted current applied to the third electrode 600c tends to decrease over time, and the predicted current applied to the second electrode 600b tends to increase slightly over time. These results may be due to the effects neighboring electrodes have on each other, which may be more accurately predicted by simulating an entire deposition process on a single seed layer (as shown in FIG. 11) than by simulating the deposition process by assuming a series of separate processes, each starting with a thicker initial seed layer (as shown in FIGS. 10A and 10B).

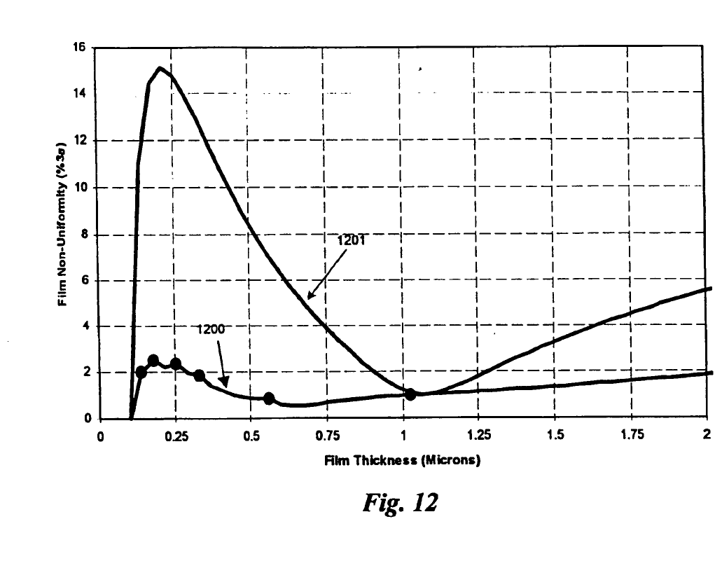

FIG. 12 illustrates the predicted film non-uniformity as a function of film thickness for a six-stage process in accordance with an embodiment of the invention (line 1200) compared with an existing single-stage process optimized for uniform current density at a film thickness of 1 micron. The predictions are for a total current of 15 amps transmitted through an electrolytic solution having a conductivity of 511 millisiemens per centimeter (mS/cm). In this prediction, the shield 580 (FIG. 4) has an inner diameter of 290 mm and is positioned 11 mm beneath the workpiece 101. The workpiece has an initial seed layer thickness of 1,000 Å. The non-uniformity is indicated as a percentage of the 3-σ deviation level of a standard distribution curve (“% 3-σ”). In other embodiments, the total current changes with time, the conductivity has other values, and/or the shield 580 has different arrangements.

As shown in FIG. 12, the multi-stage process indicated by line 1200 produces an applied film that is significantly more uniform than that resulting from the single-stage process indicated by line 1201, at all thicknesses other than about one micron. For example, in one embodiment, the multi-stage process produces an applied layer having a uniformity of 10% of 3-σ or better. In another embodiment, the uniformity is 5% of 3-σ or better. As is also shown in FIG. 12, the single-stage process produces an optimally uniform film at only one point (about 1 micron). This is because the single-stage process tends to overplate the edge of the workpiece 101 in the beginning of the process (due to the terminal effect) and underplate the edge of the workpiece 101 toward the end of the process (to account for the earlier overplating). If the process continues beyond the design point (e.g., beyond about 1 micron), the single-stage process will continue to underplate the edge of the workpiece 101, resulting in an increasingly non-uniform conductive layer. By contrast, the multi-stage process tends to produce a uniform layer at all phases of the process, and can accordingly continue beyond the design point without a substantial increase in non-uniformity.

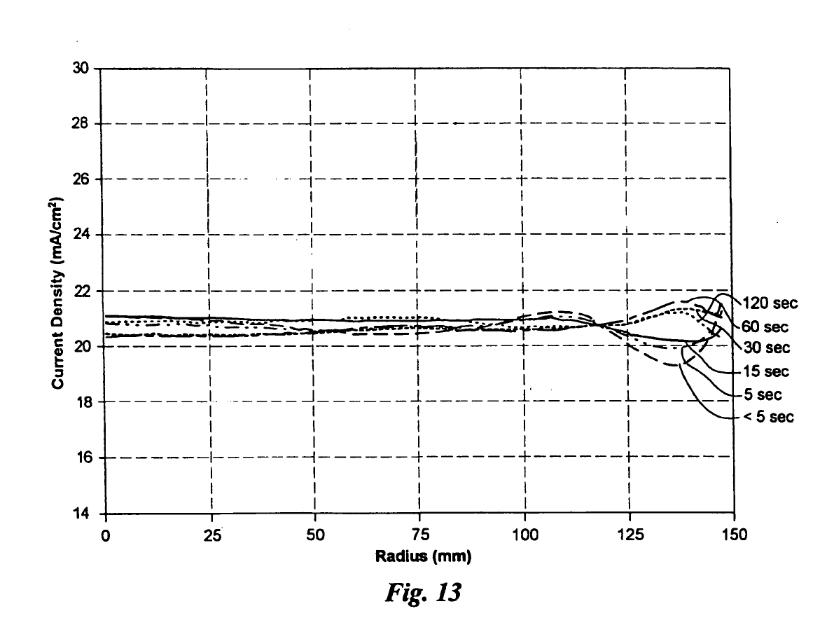

FIG. 13 illustrates predicted current densities as a function of workpiece radius at several points in time during an embodiment of the multi-stage process described above with reference to FIGS. 11 and 12. As shown in FIG. 13, the current density is generally uniform (at a level of from about 20.5 mA/cm² to about 21 mA/cm²) from the center of the workpiece 101 to a radius of about 125 mm for all phases of the process. At the outer periphery of the workpiece 101, the current density varies between about 19.5 mA/cm² to about 21.5 mA/cm² over the course of the process. Accordingly, the current density variation over the entire workpiece 101 is about 2 mA/cm² (21.5 mA/cm² minus 19.5 mA/cm²).

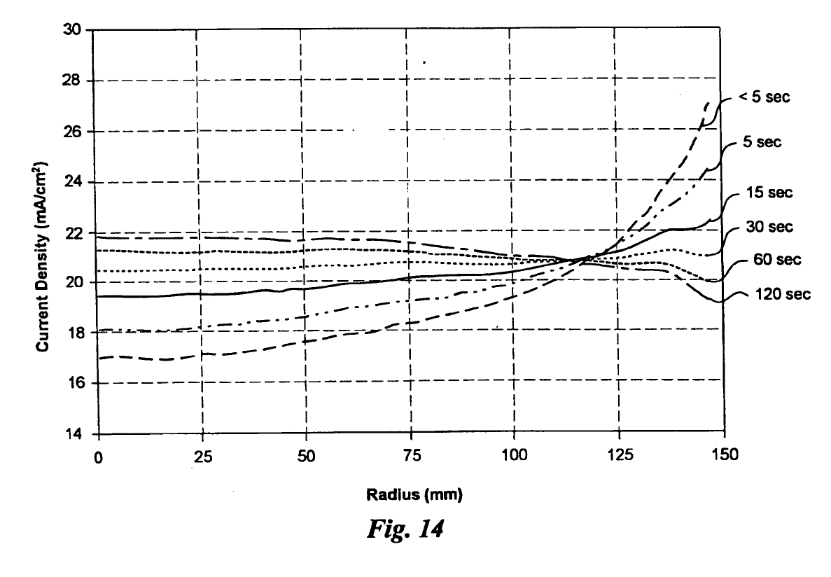

By way of comparison, FIG. 14 illustrates predicted current densities as a function of workpiece radius for an existing single-stage process, at the same points in time shown in FIG. 13. As is seen in FIG. 14, the existing single-stage process produces a significantly less uniform current density distribution than does an embodiment of the multi-stage process described above with reference to FIG. 13. For example, the current density over the inner 125 mm of the workpiece 101 varies from about 17 mA/cm² to about 21.75 mA/cm². The current density over the outer 25 mm of the workpiece 101 varies from about 19.5 mA/cm² to about 27 mA/cm². Accordingly, the current density variation over the entire workpiece is about 10 mA/cm². (27 mA/cm² minus 17 mA/cm²), significantly greater than the 2 mA/cm² variation described above with reference to FIG. 13.

One feature of an embodiment of a process described above with reference to FIGS. 10A-13 is that the current passing through each electrode (and/or the percentage of the total current contributed by each electrode) changes during the process. An advantage of this arrangement is that the local current density at each point on the workpiece is more uniform throughout the course of the process. As a result, the layer of conductive material applied to the microelectronic workpiece 101 is also more uniform at all times. This advantage can have increasing significance as the features that are filled by the conductive material decrease in size. For example, while existing processes may produce a blanket layer that is uniform at its target thickness (e.g., at 1 micron, as indicated by line 1201 shown in FIG. 12), the non-uniform plating rate during earlier phases of the process may have significant drawbacks. In particular, the electrolytic solution may include additives or other chemicals that promote uniform film growth, but that operate best at selected current densities and/or material application rates. By keeping the current density uniform over the surface of the workpiece 101 throughout the process, a method in accordance with an embodiment of the invention increases the likelihood that these additives perform well, and reduces the likelihood that non-uniformities form in the conductive material applied to the workpiece 101. The performance of the additives generally becomes more important as the size of the features decreases and the aspect ratio of the features increases.

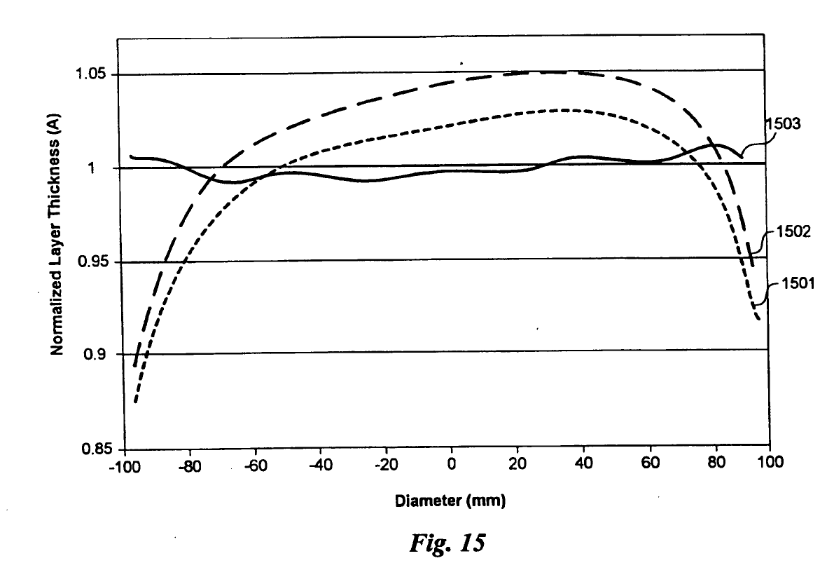

FIGS. 11-13 (described above) illustrate six-stage processes for producing uniform blanket layers on generally uniform seed layers. In other embodiments, the process can have other numbers of stages, other starting seed layer shapes and/or other blanket layer shapes. For example, FIG. 15 illustrates experimental results for a two-stage process that operates on an initially domed seed layer (represented by line 1501). The data shown in FIG. 15 are normalized to the average thickness at each stage of the process. During a first stage of the process, features in the seed layer are filled to produce the profile represented by line 1502. Because the shape of line 1502 is similar to that of line 1501, the current density was uniform during the first stage of the process. During a second stage of the process, material is applied to the filled seed layer with the current applied to at least one of the electrodes changed from the level applied during the first stage. At the end of the second stage, the applied layer has a generally uniform thickness, as represented by line 1503.

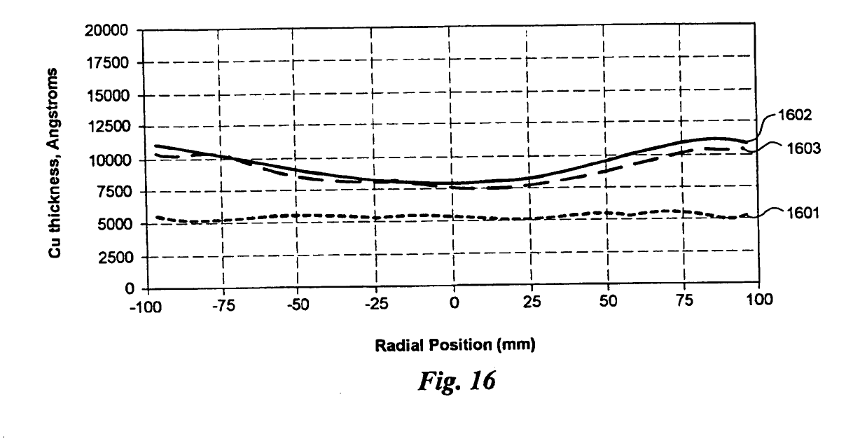

In another embodiment, shown in FIG. 16, the workpiece has an initially generally flat seed layer profile (indicated by line 1601). The target profile for the blanket layer is indicated by line 1602 and has a generally concave distribution. Line 1603 indicates an actual profile produced using a three-stage process and an apparatus generally similar to that described above with reference to FIGS. 2-8. In one aspect of this embodiment, the current was applied to the electrodes according to a first distribution during a first stage of the process. The current was changed to a non-DC application after the features of the seed layer were filled (during a second stage of the process), and distribution of the current to the electrodes was changed prior to a third, bulk fill stage of the process.

In other embodiments, multi-stage processes are used to apply material to a variety of different types of seed layers (or other layers or features), to produce a variety of different types of blanket layers (or other layers or features). For example, in one embodiment, multi-stage processes apply material at a generally uniform current density to a generally uniform seed layer, or a concave seed layer, or a convex seed layer, to produce any of a generally uniform blanket layer, a concave blanket layer, or a convex blanket layer.

In other embodiments, other characteristics of the material application process are controlled in conjunction with controlling the current applied to each of the electrodes to provide increased control over the resulting applied conductive layers. For example, in one embodiment the size of the opening in the shield 580 (FIG. 4) is adjusted to control the electrical field and/or the interaction between the electrolytic fluid and the peripheral region of the microelectronic workpiece. In another embodiment, the spacing between the shield 580 and the microelectronic workpiece is adjusted. In still further embodiments, the configuration and/or position of a diffuser in the electrolytic fluid is adjusted to control the electrical field proximate to the microelectronic workpiece, and/or the interaction between the fluid and the microelectronic workpiece.

In yet a further embodiment, the conductivity of the electrolytic solution in which the microelectronic workpiece is positioned is adjusted and, in one embodiment, has a value of between about 5 mS/cm and about 500 mS/cm. In other embodiments, the conductivity of the electrolytic fluid has values above or below this range. In one particular embodiment, the distribution of current applied to the electrodes is adjusted as a function of the conductivity of the bath. Accordingly, the distribution of the total current applied to the electrodes is different when the bath has a low conductivity than when the bath has a high conductivity. An advantage of this process is that the same processing chamber and electrode arrangement is suitable for use with electrolytic fluids having a variety of conductivities (with or without changing the hardware of the processing chamber) to process different types of workpieces. For example, some workpieces (in particular, those with very thin starting seed layers) may accumulate additional conductive material more uniformly when in contact with low conductivity electrolytic fluids, while the same or other workpieces may benefit from subsequent process stages that produce better results when the workpiece is in contact with high conductivity electrolytic fluids.

In another embodiment, the current applied to the electrodes is adjusted to add material to one portion of the microelectronic workpiece and remove material from another portion of the microelectronic workpiece. For example, in one embodiment, the current applied to all the electrodes 600a-d is reversed, with current applied to the outer-most electrode 600d greater than the current applied to the inner electrodes 600a-c. Accordingly, the electrodes 600a-d operate as cathodes to remove material from the workpiece (and remove material from the outer portion of the workpiece. After a selected period of time has passed, material is applied to both the inner and outer regions of the workpiece. In another embodiment, the outer electrode 600d can operate as a thieving electrode to attract conductive material in the electrolytic solution that would otherwise plate to the peripheral region of the workpiece. In still another arrangement, a separate thieving electrode positioned outwardly from the electrodes 600a-d shown in FIG. 4 attracts some of the conductive material in the electrolytic fluid while the remaining electrodes plate the remainder of the workpiece. In any of the foregoing embodiments, the rate at which conductive material is removed from the microelectronic workpiece, or thieved prior to attaching to the microelectronic workpiece, can change during the course of the process.

In still further embodiments, the process includes other numbers and/or sequences of process stages. For example, in one embodiment the currents applied to the electrodes vary continuously rather than in discrete stages. In other embodiments the current is applied to more than four electrodes or fewer than four electrodes. In any of the foregoing embodiments in which material is applied to, removed from or thieved from particular regions of the microelectronic workpiece, material may also be applied to, removed from or thieved from, respectively, other regions of the microelectronic workpiece, but at a slower rate. For example, when material is removed from the outer region of the workpiece, it is preferntially removed from the outer region, but may also be removed from the inner region at a slower or less preferential rate.

From the foregoing, it will be appreciated that specific embodiments of the invention have been described herein for purposes of illustration, but not various modifications may be made without deviating from the spirit and scope of the invention. Accordingly, the invention is not limited except as by the appended claims.

1-94. (canceled)

95. A method for electroplating a substantially uniform layer of a metal onto a workpiece having a seed layer thereon, the method comprising:
(a) immersing at least that portion of the workpiece having the see layer thereon in a electrolyte, said electrolyte containing ions of the metal; and
(b) passing a current between the seed layer and a plurality of anodes whereby the current is distributed among the plurality of anodes such that, for any instance in time during plating, the metal is deposited substantially uniformly onto the entire surface area of the seed layer.

96. The method of claim 95, wherein the workpiece is a wafer and the seed layer covers the front side work surface of the wafer.

97. The method of claim 96, wherein the entire surface area of the seed layer consists of an inner and an outer region, said inner region comprising a circular surface area, the center of said circular surface area coincident with the center of the wafer, said outer region comprising an annular surface area defamed by the outer circle, substantially coincident with the outermost edge of the wafer, and an inner circle of the same diameter as the inner region.

98. The method of claim 97, wherein (b) comprising distributing the current between an inner anode, proximate to the inner region, and an outer anode, proximate to the outer region.

99. The method of claim 98, wherein the inner and outer anodes comprise a pair of concentric rings positioned substantially parallel to the wafer, said pair of concentric rings' common center sharing an axis perpendicular to and passing through the center of the wafer, the inner anode's outer diameter being smaller than the inner diameter of the outer anode.

100. The method of claim 99, wherein an inner focusing cylinder, and an outer focusing cylinder are used to channel the current density in the electrolyte during plating for each of the inner and outer anodes, respectively, to the inner and outer regions, respectively.

101. The method of claim 100, wherein the inner region comprises between about 15 and 25 percent of the surface area of the seed layer exposed to the electrolyte, the outer region comprising the remainder of the surface area of the seed layer.

102. The method of claim 100, wherein the topmost apertures of each of the inner and outer focusing cylinders are between about 0.5 and 1.5 inches from the surface of the wafer during electroplating.

103. The method of claim 102, wherein the topmost apertures of each of the inner and outer focusing cylinders are about 1 inch from the surface of the wafer during electroplating.

104. The method of claim 100, wherein the distance between the topmost portion of the inner focusing cylinder and the wafer is between about four and ten times the thickness of the inner focusing cylinder walls.

105. The method of claim 100, wherein the walls of at least the inner focusing cylinder are between about 0.1 and 0.4 inches thick.

106. The method of claim 100, wherein the walls of at least the inner focusing cylinder are between about 0.1 and 0.25 inches thick.

107. The method of claim 100, further comprising shielding a circumferential edge portion of the seed layer from plating current during electroplating.

108. The method of claim 107, wherein the circumferential edge portion comprises between about 1 and 10 percent of the entire surface area of the seed layer.

109. The method of claim 107, wherein the circumferential edge portion comprises between about 3 and 5 percent of the entire surface area of the seed layer.

110. The method of claim 107, wherein shielding the circumferential edge portion of the seed layer from plating current during electroplating comprises use of a perforated shield to obtain a time-averaged shielding of the edge portion via relative movement between the wafer and the perforated shield.

111. The method of claim 95, further comprising providing a substantially uniform laminar flow of the electrolyte which impinges the wafer perpendicular to the wafer's work surface during plating.

112. The method of claim 111, wherein the total flow of electrolyte which impinges on the wafer is between about 3 and 20 liters per minute.

113. The method of claim 96, wherein (b) comprises:
i. distributing the current between a first anode, said first anode proximate an inner region of the seed layer, and a second anode, said second anode proximate an outer region of the seed layer, such that the inner region is exposed to a larger fraction of the resultant current per unit area than the outer region during an initial stage of plating; and
ii. redistributing the current between the first and second anodes toward a distribution that corresponds substantially to the ratio of the work surface areas of the first and second anode or work surface areas of any corresponding virtual anodes for each of the first and the second anodes; wherein the work surface areas of each of the first and second anodes and the work surfaces of said any corresponding virtual anodes for each of the first and the second anodes correspond substantially to the areas of the inner and outer regions of the seed layer, respectively.

114. A plating cell for electroplating a substantially uniform layer of a metal onto a wafer, the plating cell comprising:
(a) a wafer holder, configured such that the wafer or a metal seed layer thereon serves as a cathode in the plating cell, said wafer holder capable of positioning the wafer in a plating bath of the plating cell;
(b) an inner anode located within the plating bath, said inner anode comprising a ring shape, the work surface of said inner anode comprising a ring shape, the work surface of said inner anode comprising a surface area that corresponds to between about 15 and 25 percent of the platable surface area of the wafer;
(c) an outer anode, said outer anode comprising a ring shape, said outer anode concentric with the inner anode, the work surface of said outer anode comprising a surface area that corresponds to between about 75 and 85 percent of the platable surface area of the wafer;
(d) an inner focusing cylinder, between the inner and outer anodes, configured to focus a first portion of a total cell current in an electrolyte passing between the cathode and the inner anode during a plating process;
(e) an outer focusing cylinder, housing the outer anode, configured to focus a second portion of the total cell current in the electrolyte passing between the cathode and the outer anode during the plating process; and
(f) a circuit for independently adjusting the first and second portions of the total cell current supplied to each of the inner and outer anodes.

115. The plating cell of claim 114, wherein the walls of at least the inner focusing cylinder are between about 0.1 and 0.4 inches thick.

116. The plating cell of claim 114, wherein the walls of at least the inner focusing cylinder are between about 0.1 and 0.25 inches thick.

117. The plating cell of claim 114, wherein the inner and outer focusing cylinders comprise an insulating material that is chemically compatible with the electrolyte.

118. The plating cell of claim 117, wherein the insulating material comprises at least one of plastic, nanoporous ceramic, and glass.

119. The plating cell of claim 114, wherein the inner focusing cylinder has an inner diameter at its topmost portion of between about 4 and 5 inches, for a 300 mm wafer.

120. The plating cell of claim 114, wherein the inner focusing cylinder has an inner diameter at its topmost portion of between about 4.1 and 5 inches, for a 300 mm wafer.

121. The plating cell of claim 114, wherein the inner focusing cylinder has an inner diameter at its topmost portion of between about 2.5 and 3.6 inches, for a 200 mm wafer.

123. The plating cell of claim 114, wherein the outer focusing cylinder has an inner diameter at its topmost portion of approximately the diameter of the wafer.

124. The plating cell of claim 114, further comprising a shielding element configured to shield a circumferential edge portion of the wafer from plating current during electroplating.

125. The plating cell of claim 124, wherein the shielding element comprises a perforated ring shield proximate to the topmost portion of the outer focusing cylinder.

126. The plating cell of claim 114, further comprising an electrolyte inlet, configured to supply a flow of the electrolyte to the plating bath, said electrolyte inlet delivering the electrolyte through substantially the center of the inner anode.

127. The plating cell of claim 126, wherein the electrolyte inlet comprises a plurality of flow flutes.

128. The plating cell of claim 127, wherein the plurality of flow flutes are configured to distribute the flow of the electrolyte between the space encompassed by the inner focusing cylinder, and the space between the inner and outer focusing cylinder.

129. The plating cell of claim 128, wherein the plurality of flow flutes distribute the electrolyte flow via a plurality of holes along each of their lengths.

130. The plating cell of claim 129, wherein the plurality of holes are positioned on a surface of each of the plurality of flow flutes that faces the work surfaces of the inner and outer anodes.
